(19) United States
(12) Patent Application Publication
(10) Pub. No.: US 2006/0197592 A1
(43) Pub. Date: Sep. 7, 2006

(54) VARIABLE GAIN AMPLIFIER

(76) Inventor: Chia-Jun Chang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/307,421

(22) Filed: Feb. 7, 2006

(30) Foreign Application Priority Data
Mar. 1, 2005 (TW) 094106093

(51) Int. Cl. H03F 1/36

(52) U.S. Cl. 330/86

(57) ABSTRACT

A variable gain amplifier includes a first, second, and third impedances, an OP amplifier, and a control circuit. The OP amplifier has a first input end and an output end; the output end for generating outputting an output signal. Two ends of the first impedances are coupled to an input signal and the first input end respectively. Two ends of the second impedances are coupled to the first input end and the output end respectively. An end of the third impedance is coupled between the first impedance and the first input end. The control circuit is coupled to the first and third impedances. The control circuit adjusts impedance values of the first and third impedances to change a gain of the variable gain amplifier and to maintain a substantially constant DC offset at the output end.

### BACKGROUND OF THE INVENTION

1. Field of the Invention

The invention relates to a variable gain amplifier, and more particularly, to a variable gain amplifier generating an output signal with a substantially constant DC offset.

2. Description of the Prior Art

Variable gain amplifiers, whose function is to amplify an input signal according to a variable gain and thereby generate an output signal, are common elements in circuit design. They are applied extensively, and have the advantage of being applicable to both signal-ended structures and differential-ended structures.

However, one or more nodes in a variable gain amplifier may have a DC offset. When the variable gain of the amplifier is changed through adjusting a variable resistor of the amplifier, the DC offset of the output signal also correspondingly changes. This is not a desired condition for a designer.

### SUMMARY OF THE INVENTION

It is therefore an objective of the claimed invention to provide a variable gain amplifier whose output signal having a substantially constant DC offset.

According to a first embodiment of the claimed invention, a variable gain amplifier is disclosed, comprising: an OP amplifier having one input end and one output end, where the output end is used for outputting an output signal; a first impedance where two ends of the impedance are coupled to an input signal and a first input end respectively; a second impedance where two ends of the second resistor are coupled to the first input end and the output end respectively; a third impedance where one end of the third impedance is coupled between the first impedance and the first input end; and a control circuit that is coupled to the third impedance and the first impedance, for adjusting the impedance values of the first and the third impedances, thus changing the gain of the variable gain amplifier and maintaining a substantially constant output DC offset at the output end.

These and other objectives of the present invention will no doubt become obvious to those of ordinary skill in the art after reading the following detailed description of the preferred embodiment that is illustrated in the various figures and drawings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a variable gain amplifier according to the present invention.

### DETAILED DESCRIPTION

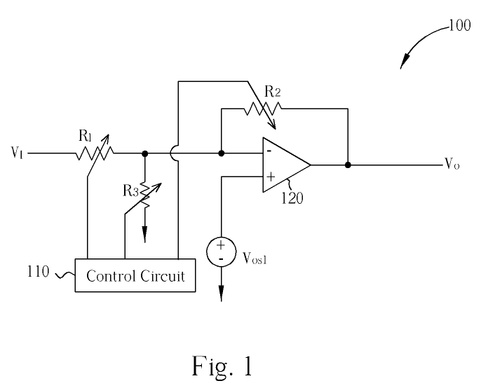

Please refer to FIG. 1 showing a schematic diagram of a variable gain amplifier according to an embodiment of the present invention. In this embodiment, the variable gain amplifier 100 comprising a control circuit 110, an operational amplifier 120, and three resistors R₁, R₂, R₃. The variable gain amplifier 100 is used for amplifying an input signal V₁ into an output signal V_{O}, where two ends of the first resistor R₁ are respectively coupled to the input signal V_{I} and a first input end of the operational amplifier 120, two ends of the second resistor R₂ are respectively coupled to the first input end and an output end of the operational amplifier 120, and one end of the third resistor R₃ is coupled between the first resistor and the first input end of the operational amplifier while the other end of the third resistor is coupled to virtual ground. In this embodiment, the first, second, and third resistors, R₁, R₂, and R₃ are variable resistors. The control circuit 110 is coupled to R₁, R₂, and R₃ for tuning the resistances of these three resistors.

Ideally, a second input end of the variable gain amplifier 100 should couple to virtual ground. However, there probably exists a DC offset voltage V_{OS1} at the second end of the operational amplifier 120. This DC offset voltage V_{OS1} may therefore cause a DC offset voltage V_{OS2} at the output end of the variable gain amplifier 100 (i.e. a DC offset component V_{OS2} exists in the output signal V_{O}). Taking the circuit structure in FIG. 1 as an example, V_{OS2} can be expressed as V_{OS2}=VOS₁×[1+R₂(R₁+R₃)/(R₁×R₃)]. Because the gain of the variable gain amplifier 100 is substantially equal to (−R₂/R₁), a way for the control circuit 110 to change the gain of the variable gain amplifier 100 is by tuning the resistance of the first resistor R₁ or the second resistor R₂ (or tuning the resistances of the first resistor R₁ and the second resistor R₂ at the same time). If there is no third resistor R₃, then after the resistances of the first resistance R₁ or the second resistor R₂ have changed, the DC offset V_{OS2} will be changed accordingly (i.e. the DC component V_{OS2} of the output signal V_{O} is changed accordingly).

In order to keep the DC offset V_{OS2} at the output end substantially constant, the third resistor R₃ is applied to the variable gain amplifier 100. Furthermore, the resistance of the third resistor R₃ is changed by the control circuit 110 while the control circuit 110 also changes the gain of the variable gain amplifier 100 by tuning the resistance of the first resistor R₁ or the second resistor R₂ (or tuning the resistances of the first resistor R₁ and the second resistor R₂ at the same time), thus maintaining a substantially constant DC offset V_{OS2} at the output end. More precisely, while changing the gain of the variable gain amplifier 100, the control circuit 110 will substantially keep [R₂(R₁+R₃)/(R₁×R₃)] at a substantially constant value, therefore enabling the DC offset V_{OS2} at the output end to remain unchanged. Once the control circuit 110 begins to change the gain of the variable gain amplifier 100 by tuning the first resistor R₁ (while keeping the resistance of the second resistor R₂ the same), the control circuit 110 only needs to tune the resistance of the third resistor R₃ accordingly to maintain the value (R₁+R₃)/(R₁×R₃) at a substantially constant value. The DC offset V_{OS2} at the output end then remains substantially constant.

There are many ways to realize the first, second, and third resistors R₁, R₂, and R₃. For example, the first, second, and third resistors R₁, R₂, and R₃ can comprise several resistors in parallel and several corresponding switches. The control circuit 110 can turn on or turn off the switches to tune the resistances of the first, second, and third resistors R₁, R₂, and R₃. The control circuit 110 can include a look-up table, which it references to determine whether to turn on or turn off each switch in the design in order to keep the value of the output signal's DC component V_{OS2} substantially constant while changing the gain of the variable gain amplifier 100. Moreover, a designer can use transistors to realize the first, second and third resistors R₁, R₂, and R₃, enabling the control circuit 110 to modify the resistance of the respective resistor by tuning the control voltage at the control end of each transistor (whereby the control circuit 100 performs the task according to a look-up table).

Please note that in the examples mentioned above a single-ended variable gain amplifier is described. This is merely an embodiment of the present invention and should not be considered as a limitation. It would be simple for a person skilled in the art to apply the concept of this invention to a differential-ended variable gain amplifier, and a related description is thus omitted here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A variable gain amplifier, comprising:
an operational amplifier having a first input end and an output end, the output end for outputting an output signal;
a first impedance having two ends coupled to an input signal and the first input end respectively;
a second impedance having two ends coupled to the first input end and the output end respectively;
a third impedance having an end coupled between the first impedance and the first input end; and
a control circuit coupled to the third impedance and at least one of the first impedance and the second impedance, for adjusting impedance values of third impedance and at least one of the first and second impedances to change a gain of the variable gain amplifier and to maintain a substantially constant DC offset of the output signal.

2. The variable gain amplifier of claim 1, wherein the control circuit maintains a substantially constant parallel impedance value of the first and third impedances.

3. The variable gain amplifier of claim 1, wherein the impedance values of the first, second, and third impedances are Z₁, Z₂, and Z₃ respectively, and the control circuit maintains [Z₂(Z₁+Z₃)/(Z₁×Z₃)] at a substantially constant value.

4. The variable gain amplifier of claim 1, wherein at least one of the first, second and third impedances comprises a plurality of resistors and a plurality of switches, and the control circuit controls states of the switches to adjust at least one of the impedance values of the first, second and third impedances.

5. The variable gain amplifier of claim 1, wherein the third impedance has another end coupled to virtual ground.

6. A variable gain amplifier, comprising:
an operational amplifier having a first input end and an output end, the output end for outputting an output signal;
a first impedance having two ends coupled to an input signal and the first input end respectively;
a second impedance having two ends coupled to the first input end and the output end respectively;
a third impedance having an end coupled between the first impedance and the first input end;
wherein the first and third impedances have adjustable impedance values; when the impedance value of the first impedance is changed, the impedance value of the third impedance is also changed to maintain a parallel impedance value of the first and third impedances at a substantially constant value, and a substantially constant DC offset of the output signal is therefore maintained.

7. The variable gain amplifier of claim 6, wherein the second impedance has an adjustable impedance value; when the impedance value of the second impedance is changed, the impedance value of the first or third impedance is also changed to maintain the substantially constant DC offset of the output signal.

8. The variable gain amplifier of claim 7, wherein the impedance values of the first, second, and third impedances are Z₁, Z₂, and Z₃ respectively, and [Z₂(Z₁+Z₃)/(Z₁×Z₃)] is maintained at a substantially constant value.

9. The variable gain amplifier of claim 7, wherein the second impedance comprises a plurality of resistors and a plurality of switches, and the impedance value of the second impedance changes in accordance with states of the switches.

10. The variable gain amplifier of claim 6, wherein at least one of the first and third impedance comprises a plurality of resistors and a plurality of switches, and at least one of the impedance values of the first and third impedances changes in accordance with states of the switches.

11. The variable gain amplifier of claim 6, wherein the third impedance has another end coupled to virtual ground.

12. The variable gain amplifier of claim 6 further comprising a control circuit coupled to the first and third impedance, for controlling the impedance values of the first and third impedances.

13. A variable gain amplifier, comprising:
an operational amplifier having a first input end and an output end, the output end for outputting an output signal;
a first impedance having two ends coupled to an input signal and the first input end respectively;
a second impedance having two ends coupled to the first input end and the output end respectively;
a third impedance having two ends coupled to the first impedance and virtual ground respectively; and
a control circuit coupled to the third impedance and at least one of the first impedance and the second impedance, for adjusting impedance values of third impedance and at least one of the first and second impedances to change a gain of the variable gain amplifier and to maintain a substantially constant DC offset of the output signal.

14. The variable gain amplifier of claim 13, wherein the control circuit maintains a substantially constant parallel impedance value of the first and third impedances.

15. The variable gain amplifier of claim 13, wherein the impedance values of the first, second, and third impedances are Z₁, Z₂, and Z₃ respectively, and the control circuit maintains [Z₂(Z₁+Z₃)/(Z₁×Z₃)] at a substantially constant value.

16. The variable gain amplifier of claim 13, wherein at least one of the first, second and third impedances comprises a plurality of resistors and a plurality of switches, and the control circuit controls states of the switches to adjust at least one of the impedance values of the first, second and third impedances.
